(19) United States
(12) Patent Application Publication
(10) Pub. No.: US 2010/0230760 A1
(43) Pub. Date: Sep. 16, 2010

(54) Silicon Wafer Having Interconnection Metal

(76) Inventor: Cheng-Hui Hung, Kaohsiung (TW)

Correspondence Address: MCCRACKEN & FRANK LLP, 311 S. WACKER DRIVE, SUITE 2500, CHICAGO, IL, 60606, US

(21) Appl. No.: 12/706,427

(22) Filed: Feb. 16, 2010

(30) Foreign Application Priority Data
Mar. 13, 2009 (TW) 098108313

(51) Int. Cl. H01L 23/48; H01L 27/092

(52) U.S. Cl. 257/369; 257/621; 257/E27.062; 257/E23.011

(57) ABSTRACT

The present invention relates to a silicon wafer having interconnection metal. The silicon wafer includes a silicon substrate, at least one electrical device, a barrier layer, a metal layer, at least one first interconnection metal and at least one second interconnection metal. The electrical device is disposed in the silicon substrate, and exposed to a first surface of the silicon substrate. The barrier layer is disposed on the first surface of the silicon substrate. The metal layer is disposed on a surface of the barrier layer. The first interconnection metal penetrates the barrier layer, and is disposed on the electrical device. The first interconnection metal connects the metal layer and the electrical device. The second interconnection metal penetrates the barrier layer, and is disposed at a corresponding position on the outside of the electrical device. The second interconnection metal connects the metal layer. Thus, after a silicon through via is formed, the silicon through via is connected to the metal layer by the second interconnection metal, so the yield rate is raised.

### BACKGROUND OF THE INVENTION

1. Field of the Invention

The present invention relates to a silicon wafer, and more particularly to a silicon wafer having interconnection metal.

2. Description of the Related Art

FIG. 1 shows a cross-sectional view of a conventional silicon wafer having interconnection metal. The silicon wafer 1 comprises a silicon substrate 11, at least one electrical device 12, a barrier layer 13, a metal to layer 14 and at least one interconnection metal 15. The silicon substrate 11 has a first surface 111 and a second surface 112. The electrical device 12 is disposed in the silicon substrate 11, and exposed to the first surface 111 of the silicon substrate 11. The barrier layer 13 is disposed on the first surface 111 of the silicon substrate 11, and has a surface 131. The metal layer 14 is disposed on the surface 131 of the barrier layer 13. The interconnection metal 15 penetrates the barrier layer 13, and is disposed on the electrical device 12. The interconnection metal 15 connects the metal layer 14 and the electrical device 12.

The conventional silicon wafer 1 having interconnection metal has the following disadvantages. As shown in FIG. 2, when it is desired to form a silicon through via 16 in the silicon substrate 11 of the silicon wafer 1, part of the silicon substrate 11 and part of the barrier layer 13 need to be removed so as to form a through hole 17 that penetrates the silicon substrate 11 and the barrier layer 13. Then, an isolation layer 161 and a conductor 162 are formed in the through hole 17 so as to form the silicon through via 16 that connects the metal layer 14. However, since the silicon substrate 11 and the barrier layer 13 are made of different materials, during the etching process, the operation factors must be accurately controlled;

otherwise, the two situations described below will happen. First, as shown in FIG. 3, the through hole 17 only penetrates the silicon substrate 11 but not the barrier layer 13, so the silicon through via 16 cannot connect the metal layer 14. Second, as shown in FIG. 4, although the through hole 17 penetrates both the silicon substrate 11 and the barrier layer 13, a footing situation also occurs, as shown in area A. That is, the silicon substrate 11 is over-etched, and the walls 113, 132 of the silicon substrate 11 and the barrier layer 13 form a discontinuous surface, which prevents the silicon through via 16 from being formed and connecting the metal layer 14.

Therefore, it is necessary to provide a silicon wafer having interconnection metal to solve the above problems.

### SUMMARY OF THE INVENTION

The present invention is directed to a silicon wafer having interconnection metal. The silicon wafer comprises a silicon substrate, at least one electrical device, a barrier layer, a metal layer, at least one first interconnection metal and at least one second interconnection metal. The silicon substrate has a first surface and a second surface. The electrical device is disposed in the silicon substrate, and exposed to the first surface of the silicon substrate. The barrier layer is disposed on the first surface of the silicon substrate and has a surface. The metal layer is disposed on the surface of the barrier layer. The first interconnection metal penetrates the barrier layer, and is disposed on the electrical device. The first interconnection metal connects the metal layer and the electrical device. The second interconnection metal penetrates the barrier layer, and is disposed at a corresponding position on the outside of the electrical device. The second interconnection metal connects the metal layer.

Thus, when it is desired to form a silicon through via, only part of the silicon substrate needs to be removed so as to penetrate the silicon substrate. After the silicon through via is formed, the silicon through via is electrically connected to the metal layer by the second interconnection metal, so the yield rate is raised.

### BRIEF DESCRIPTION OF THE DRAWINGS

FIG. 1 is a cross-sectional view of a conventional silicon wafer having interconnection metal;

FIG. 2 is a cross-sectional view of a conventional silicon wafer having interconnection metal, wherein a silicon through via is formed in the silicon wafer;

FIG. 3 is a cross-sectional view of a conventional silicon wafer having interconnection metal, wherein the silicon through via in the silicon wafer fails to connect a metal layer in a first situation;

FIG. 4 is a cross-sectional view of a conventional silicon wafer having interconnection metal, wherein the silicon through via in the silicon wafer fails to connect a metal layer in a second situation;

FIGS. 5 to 7 are cross-sectional views of a method for making a silicon wafer having interconnection metal according to a first embodiment of the present invention;

FIG. 8 is a cross-sectional view of a silicon wafer having interconnection metal according to a second embodiment of the present invention;

FIG. 9 is a cross-sectional view of a silicon wafer having interconnection metal according to a third embodiment of the present invention; and

FIG. 10 is a partial enlarged top view of FIG. 9.

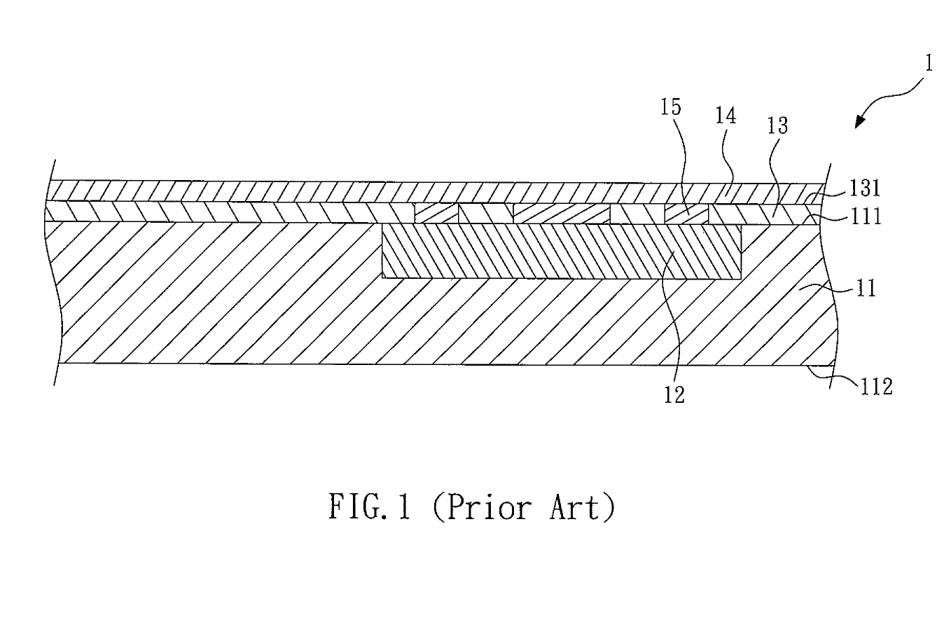

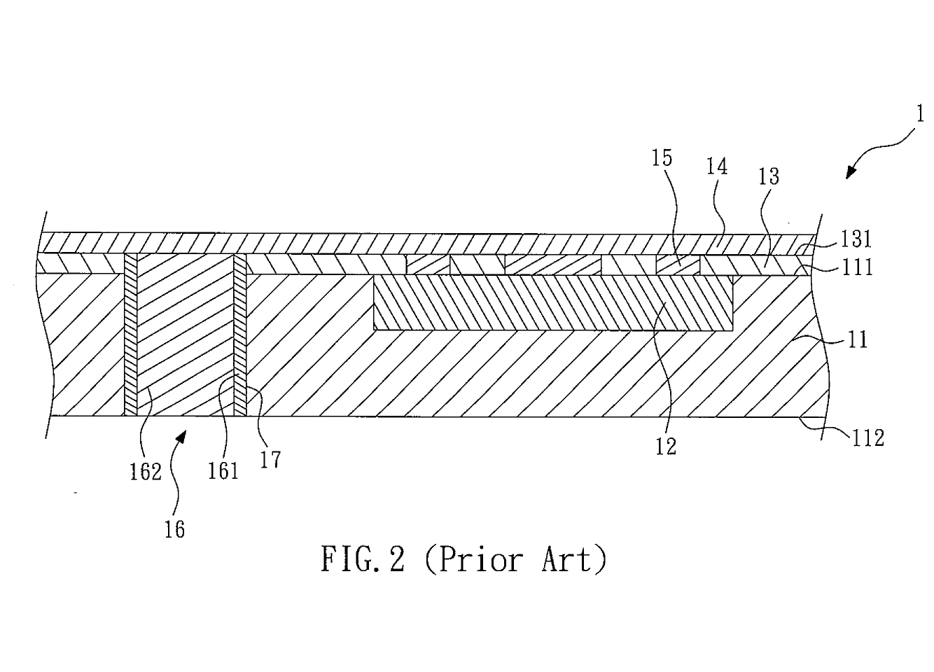

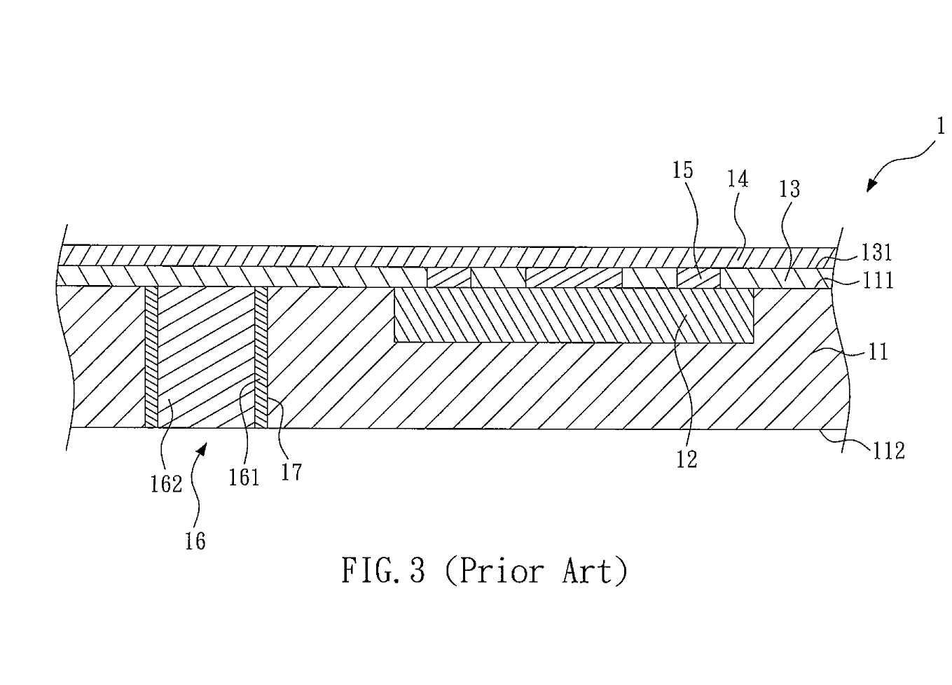

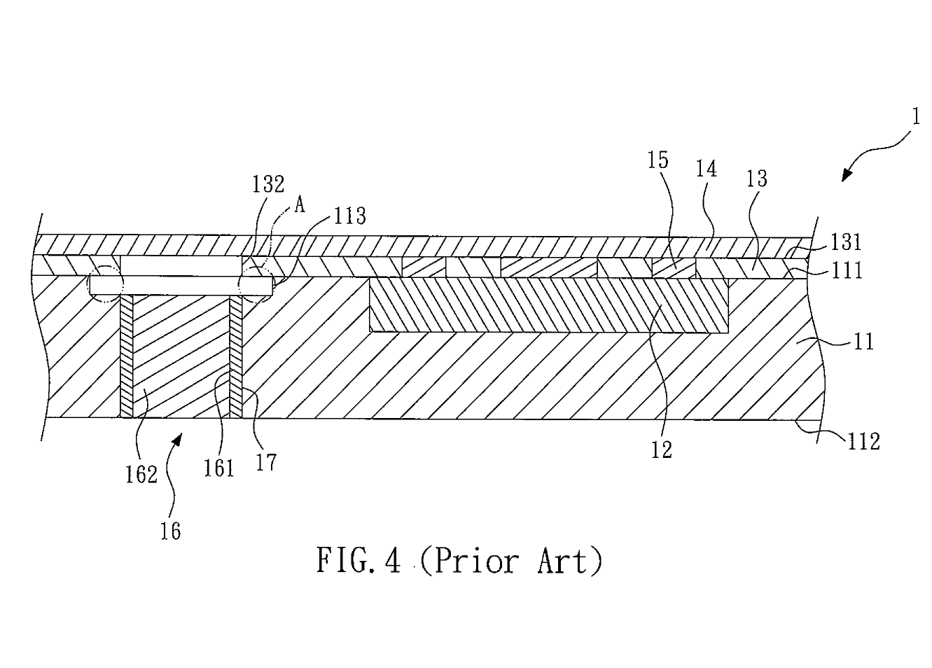

### DETAILED DESCRIPTION OF THE INVENTION

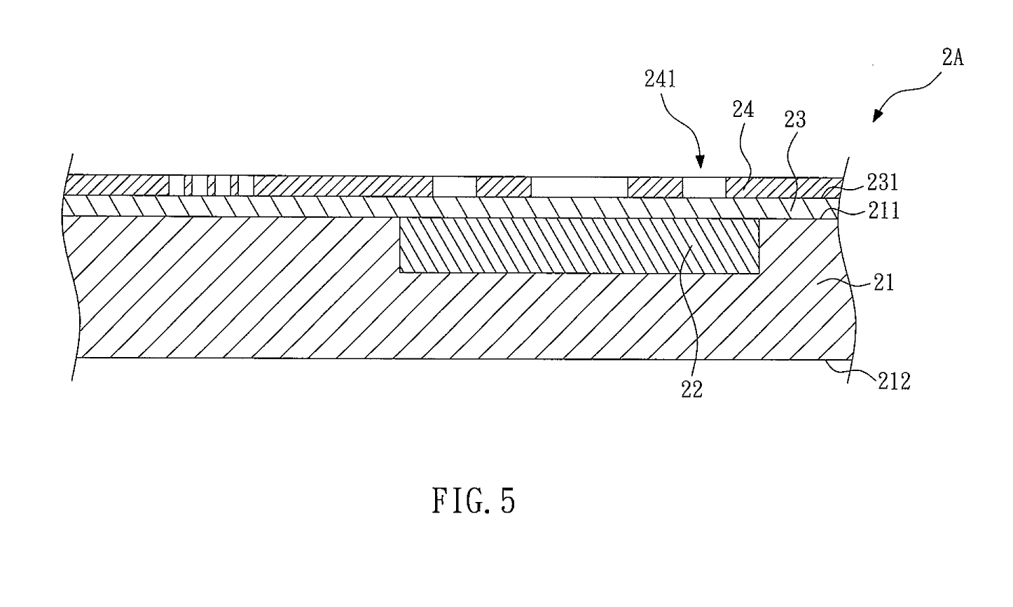

FIGS. 5 to 7 show cross-sectional views of a method for making a silicon wafer having interconnection metal according to a first embodiment of the present invention. In FIG. 5, a silicon wafer 2A is provided. The silicon wafer 2A comprises a silicon substrate 21, at least one electrical device 22 and a barrier layer 23. The silicon substrate 21 has a first surface 211 and a second surface 212. The electrical device 22 is disposed in the silicon substrate 21, and exposed to the first surface 211 of the silicon substrate 21. The electrical device 22 is preferably a transistor or a complementary metal-oxide-semiconductor (CMOS). The barrier layer 23 is disposed on the first surface 211 of the silicon substrate 21, and the barrier layer 23 has a surface 231. The material of the barrier layer 23 is preferably silicon oxide. Afterward, a photoresist 24 is formed on the surface 231 of the barrier layer 23 of the silicon wafer 2A. The photoresist 24 has at least one opening 241, and the openings 241 exposes part of the barrier layer 23. In the embodiment, the diameters of the openings 241 are different. However, in other applications, the diameters of the openings 241 are preferably the same.

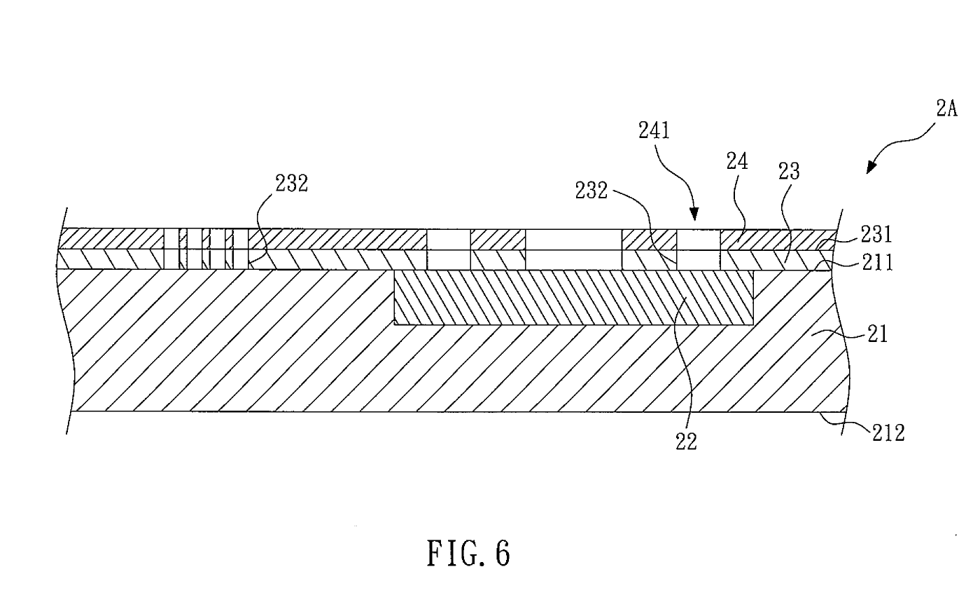

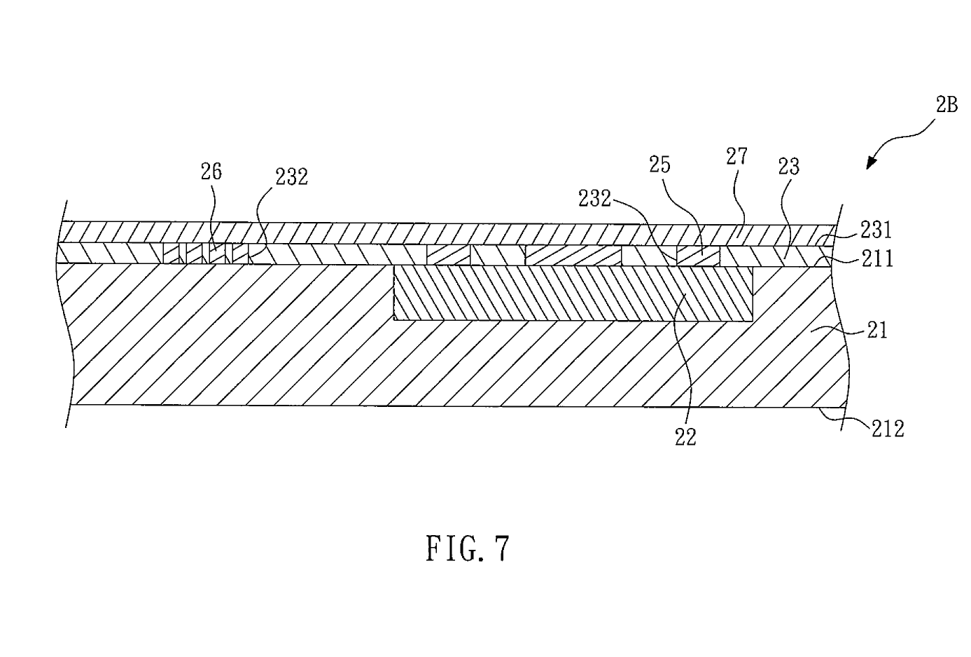

In FIG. 6, part of the barrier layer 23 which is exposed to the opening 241 of the photoresist 24 is removed so as to form at least one first through hole 232. In the embodiment, the exposed barrier layer 23 is removed by etching, and the diameters of the first through holes 232 are different. However, in other applications, the diameters of the first through holes 232 are preferably the same, and are not less than 1 pm. In FIG. 7, the photoresist 24 (FIG. 6) is removed, and a conducting metal is formed in the first through holes 232 so as to form at least one first interconnection metal 25 and at least one second interconnection metal 26. The first interconnection metal 25 is disposed on the electrical device 22, and the second interconnection metal 26 is disposed at a corresponding position on the outside of the electrical device 22. Finally, a metal layer 27 is formed on the surface 231 of the barrier layer 23 so as to form a silicon wafer 2B having interconnection metal. The first interconnection metal 25 connects the metal layer 27 and the electrical device 22, and the second interconnection metal 26 connects the metal layer 27. In the embodiment, the second interconnection metal 26 connects the metal layer 27 and the silicon substrate 21. The material of the metal layer 27 is preferably copper or aluminum, and the material of the first interconnection metal 25 and the second interconnection metal 26 is tungsten. Therefore, the metal layer 27 and the interconnection metals (the first interconnection metal 25 and the second interconnection metal 26) are made of different materials, which can avoid the lowering of the yield rate caused by metal diffusion.

FIG. 7 shows a cross-sectional view of a silicon wafer having interconnection metal according to a first embodiment of the present invention. The silicon wafer 2B comprises a silicon substrate 21, at least one electrical device 22, a barrier layer 23, a metal layer 27, at least one first interconnection metal 25 and at least one second interconnection metal 26. The silicon substrate 21 has a first surface 211 and a second surface 212. The electrical device 22 is disposed in the silicon substrate 21, and exposed to the first surface 211 of the silicon substrate 21. The electrical device 22 is preferably a transistor or a complementary metal-oxide-semiconductor (CMOS). The barrier layer 23 is disposed on the first surface 211 of the silicon substrate 21, and the barrier layer 23 has a surface 231. In the embodiment, the barrier layer 23 has a plurality of first through holes 232, and the diameters of the first through holes 232 are different. However, in other applications, the diameters of the first through holes 232 are preferably the same, and are not less than 1 μm. The material of the barrier layer 23 is preferably silicon oxide.

The metal layer 27 is disposed on the surface 231 of the barrier layer 23. The material of the metal layer 27 is preferably copper or aluminum. The first interconnection metal 25 penetrates the barrier layer 23, and is disposed on the electrical device 22. The first interconnection metal 25 connects the metal layer 27 and the electrical device 22. The second interconnection metal 26 penetrates the barrier layer 23, and is disposed at a corresponding position on the outside of the electrical device 22. The second interconnection metal 26 connects the metal layer 27. In the embodiment, the second interconnection metal 26 connects the metal layer 27 and the silicon substrate 21. The first interconnection metal 25 and the second interconnection metal 26 are disposed in the first through holes 232. The material of the first interconnection metal 25 and the second interconnection metal 26 is preferably tungsten. Therefore, the metal layer 27 and the interconnection metals (the first interconnection metal 25 and the second interconnection metal 26) are made of different materials, which can avoid the lowering of the yield rate caused by metal diffusion.

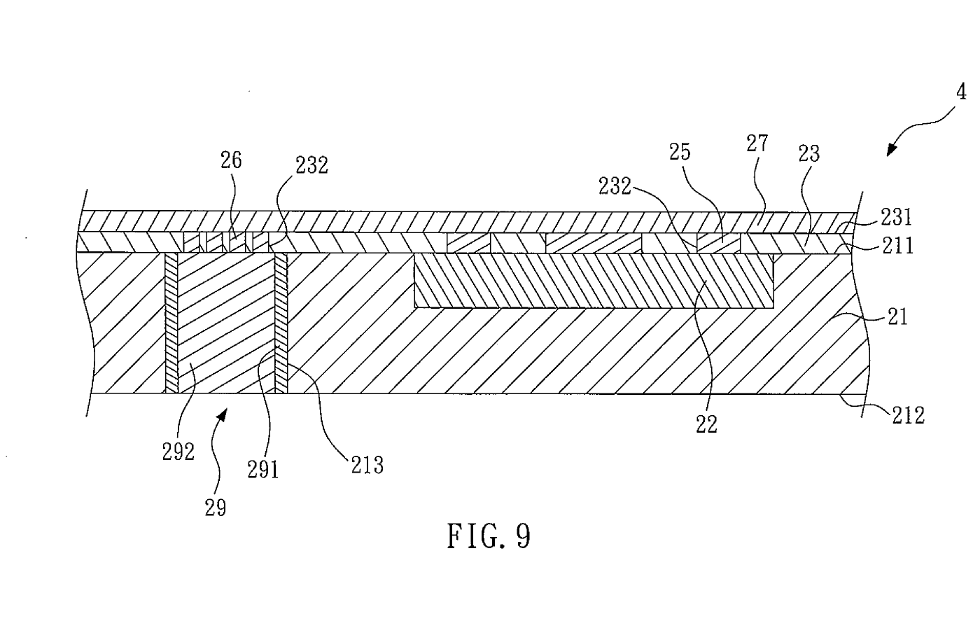

Thus, when it is desired to form a silicon through via 29 (FIG. 9), only part of the silicon substrate 21 needs to be removed so as to penetrate the silicon substrate 21. After the silicon through via 29 is formed, the silicon through via 29 is electrically connected to the metal layer 27 by the second interconnection metal 26, so the yield rate is raised, and the problems of over-etching and failure to connect the metal layer of prior art are solved.

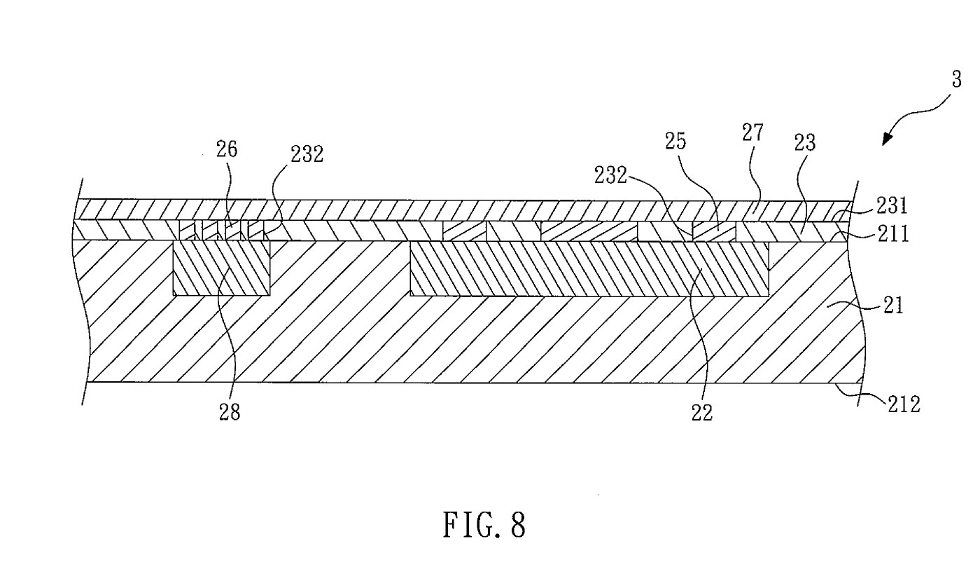

FIG. 8 shows a cross-sectional view of a silicon wafer having interconnection metal according to a second embodiment of the present invention. The silicon wafer 3 according to the second embodiment is substantially the same as the silicon wafer 2B (FIG. 7) according to the first embodiment, and the same elements are designated by the same reference numbers. The difference between the silicon wafer 3 according to the second embodiment and the silicon wafer 2B (FIG. 7) according to the first embodiment is that the silicon wafer 3 further comprises a testing device 28. In the embodiment, the testing device 28 has no electrical function. The testing device 28 is disposed in the silicon substrate 21, and is exposed to the first surface 211 of the silicon substrate 21. The second interconnection metal 26 connects the metal layer 27 and the testing device 28. The testing device 28 is to be penetrated by a silicon through via 29 (FIG. 9).

FIG. 9 shows a cross-sectional view of a silicon wafer having interconnection metal according to a third embodiment of the present invention. The silicon wafer 4 according to the third embodiment is substantially the same as the silicon wafer 2B (FIG. 7) according to the first embodiment, and the same elements are designated by the same reference numbers. The difference between the silicon wafer 4 according to the third embodiment and the silicon wafer 2B (FIG. 7) according to the first embodiment is that the silicon wafer 4 further comprises a silicon through via 29.

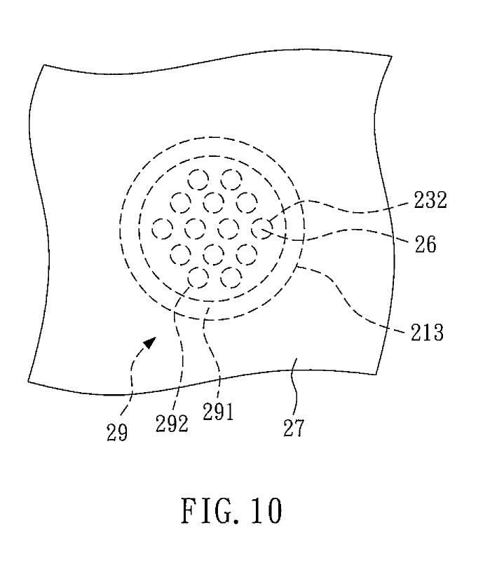

In the embodiment, the silicon through via 29 penetrates the silicon substrate 21. The silicon substrate 21 has at least one second through hole 213, and the silicon through via 29 is disposed in the second through hole 213. The silicon through via 29 comprises an isolation layer 291 and a conductor 292. The isolation layer 291 is disposed on the wall of the second through hole 213 of the silicon substrate 21, and the conductor 292 is disposed in the isolation layer 291. The material of the isolation layer 291 is polymer, and the material of the conductor 292, for example, is copper. The second interconnection metal 26 connects the metal layer 27 and the conductor 292 of the silicon through via 29. The diameters of the first through holes 232 are smaller than that of the second through hole 213, as shown in FIG. 10. In other applications, the diameters of the first through holes 232 may be the same as that of the second through hole 213.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A silicon wafer having interconnection metal, comprising:
a silicon substrate, having a first surface and a second surface;
at least one electrical device, disposed in the silicon substrate, and exposed to the first surface of the silicon substrate;
a barrier layer, disposed on the first surface of the silicon substrate, wherein the barrier layer has a surface;
a metal layer, disposed on the surface of the barrier layer;
at least one first interconnection metal, penetrating the barrier layer, and disposed on the electrical device, wherein the first interconnection metal connects the metal layer and the electrical device; and
at least one second interconnection metal, penetrating the barrier layer, and disposed at a corresponding position on the outside of the electrical device, wherein the second interconnection metal connects the metal layer.

2. The silicon wafer as claimed in claim 1, wherein the electrical device is a transistor or a complementary metal-oxide-semiconductor (CMOS).

3. The silicon wafer as claimed in claim 1, wherein the material of the barrier layer is silicon oxide.

4. The silicon wafer as claimed in claim 1, wherein the barrier layer has a plurality of first through holes, the first interconnection metal and the second interconnection metal are disposed in the first through holes, and the diameters of the first through holes are the same.

5. The silicon wafer as claimed in claim 4, wherein the diameters of the first through holes are not less than 1 μm.

6. The silicon wafer as claimed in claim 1, wherein the material of the metal layer is copper or aluminum.

7. The silicon wafer as claimed in claim 1, wherein the material of the first interconnection metal and the second interconnection metal is tungsten.

8. The silicon wafer as claimed in claim 1, wherein the second interconnection metal connects the metal layer and the silicon substrate.

9. The silicon wafer as claimed in claim 1, further comprising a testing device with no electrical function, wherein the testing device is disposed in the silicon substrate, and exposed to the first surface of the silicon substrate.

10. The silicon wafer as claimed in claim 1, further comprising at least one silicon through via, penetrating the silicon substrate.

11. The silicon wafer as claimed in claim 10, wherein the second interconnection metal connects the metal layer and the silicon through via.

12. The silicon wafer as claimed in claim 10, wherein the silicon substrate has at least one second through hole, the silicon through via is disposed in the second through hole, the silicon through via comprises an isolation layer and a conductor, the isolation layer is disposed on the wall of the second through hole of the silicon substrate, and the conductor is disposed in the isolation layer.

13. The silicon wafer as claimed in claim 12, wherein the second interconnection metal connects the metal layer and the conductor of the silicon through via.

14. The silicon wafer as claimed in claim 10, wherein the diameters of the first through holes are smaller than or the same as that of the second through hole.
